(19) United States
(12) Patent Application Publication
(10) Pub. No.: US 2002/0158622 A1
(43) Pub. Date: Oct. 31, 2002

(54) Error correction in amplifiers

(76) Inventors: Mark W. Rayne, Cambridgeshire (GB); Adrian Paul Hillier, Suffolk (GB); Geoffrey Sidney Sparks, Cambridge (GB); Dennis Anthony Culling, Cambridge (GB); Nicholas David Swales, Hardwick (GB)

Correspondence Address: SCHWEGMAN, LUNDBERG, WOESSNER & KLUTH, P.A., P.O. BOX 2938, MINNEAPOLIS, MN, 55402, US

(21) Appl. No.: 09/782,553

(22) Filed: Feb. 13, 2001

Related U.S. Application Data
(63) Continuation of application No. PCT/GB99/02681, filed on Aug. 13, 1999.

(30) Foreign Application Priority Data
Aug. 13, 1998 (GB) 9817675.3

(51) Int. Cl. G01R 23/12

(52) U.S. Cl. 324/76.53

(57) ABSTRACT

A method of estimating the loop phase error in a negative feedback amplifier is disclosed which comprises applying a test signal to the input of the amplifier, modulating the phase of the feedback signal to be summed to the test signal input to the amplifier, measuring the amplitude of the forward signal of the amplifier at two harmonics of the frequency of the phase modulation, and estimating the loop phase error on the basis of said two amplitude measurements. Apparatus for carrying out such a method is also disclosed.

This invention relates to amplifiers and more particularly to a method of estimating the loop phase error in an amplifier employing negative feedback. The invention relates most particularly, although is not limited to, Cartesian loop amplifiers such as those shown and described in EP-A-0598585 and WO 98/00908.

Negative feedback amplifiers—especially Cartesian loop amplifiers—are often used in applications requiring a high degree of linearity, for example mobile radio transceivers. It is impossible to achieve perfect linearity in a practical system and therefore some degree of distortion is inevitable. An important parameter affecting the performance and stability of such amplifiers is the error in phase between the input signal and the portion of the output signal which is fed back.

In an ideal negative feedback system, the feedback signal should be subtracted directly from the input, and thus relative phase of the input and feedback signals should be arranged to achieve this. In practice however, the loop phase (and thus the relative phase of input and feedback signals) varies as a consequence of e.g. fluctuations in operating frequency, and temperature and also through ageing. The amount by which the relative phase of the input signal and feedback signal differs from its ideal value is known as the loop phase error. Generally, the smaller the loop phase error, the better will be the performance of the overall amplifier.

A method of reducing the loop phase error in a Cartesian amplifier is set out in WO 98/00908. In this method, during predetermined linearisation timeslots or bursts, one of the quadrature components of the Cartesian loop amplifier is interrupted and a test signal is applied to the amplifier input to give a carrier wave output. The phase of the negative feedback signal is then modulated about its nominal value by a measuring oscillation. As is explained in WO 98/00908, the amplitude of the portion of the amplifier's output at the frequency of the measuring oscillation is dependent upon the loop phase error. Thus by minimising the amplitude of this AC component of the output signal, the loop phase error can be reduced.

According to a first aspect of the present invention, there is provided a method of estimating the loop phase error in a negative feedback amplifier, comprising applying a test signal to the input of the amplifier, modulating the phase of the feedback signal to be summed to the test signal input to the amplifier, measuring the amplitude of the forward signal of the amplifier at two harmonics of the frequency of the phase modulation, and estimating the loop phase error on the basis of said two amplitude measurements.

From a second aspect the invention provides an apparatus for estimating the loop phase error in a negative feedback amplifier, comprising means for applying a test signal to the input of the amplifier, means for modulating the phase of the feedback signal to be summed to the test signal input to the amplifier, means for measuring the amplitude of the forward signal of the amplifier at two harmonics of the frequency of the phase modulation, and means for estimating the loop phase error on the basis of the two amplitude measurements.

In the present invention a test signal is applied to a negative feedback amplifier and the phase of the feedback signal that is added to the test signal is modulated at a particular frequency about its nominal or mean value. Such phase modulation of the feedback signal to be added to the amplifier's input signal (i.e. the signal to be amplified) will manifest as a recoverable amplitude modulation in the forward signal (e.g. output) of the amplifier. The applicants have found that, as will be described in more detail below, the amplitude of the components of the forward signal of the amplifier under such conditions at two harmonics of the applied phase modulation (i.e. of the particular frequency) can be used to provide a more accurate and reliable estimate of the loop phase error of the amplifier than, for example, considering the amplitude of the amplifier's output at the fundamental frequency of the phase modulation alone. Because the present invention provides a better estimate of the loop phase error, it therefore can, inter alia, reduce the number of successive iterations necessary to try to reduce the loop phase error to a desired value, and potentially permit a sufficient correction in a single step.

The test signal to be applied to the input of the amplifier is preferably predetermined (so that it can be compensated for in the measurement and estimation process if necessary). It is preferably a d.c. level (such that a carrier frequency output would be acquired from a radio-frequency power amplifier), as this simplifies the loop phase error estimate calculation, although any suitable test signal can be used.

The phase modulation of the feedback signal can be achieved as desired. It can be achieved by modulating the phase of the signal anywhere within the amplifier loop, since such modulation will cause the phase of the feedback signal at the point where it is combined with the amplifier's input signal to be modulated in phase about its nominal or mean phase value. Thus the modulation can be achieved by phase shifting the amplifier loop signal in accordance with an appropriate input modulating signal at any point in the closed amplifier loop. The phase modulation could therefore be achieved, for example, by applying a phase modulating signal to the amplifier signal within the forward path of the closed amplifier loop.

However, most preferably the phase modulation is applied to the signal in the feedback path of the amplifier, as this is a particularly convenient way of modulating the feedback signal's phase and, inter alia, provides a better gain. Thus preferably, a phase modulation signal is applied or input to the feedback signal in the feedback path of the amplifier (e.g. by means of a phase modulating means arranged to modulate the phase of the signal in the feedback path of the amplifier).

The phase of the feedback signal of the amplifier can be modulated as desired. It is preferably modulated at a predetermined single frequency, and preferably at a predetermined amplitude. Thus the phase modulation signal applied to the amplifier loop signal (e.g. the signal in the feedback path) could, for example, be of the form d. sin ωt.

The two harmonics at which the amplitude of the forward signal is measured can be selected as desired. They could comprise the fundamental frequency (i.e. the first harmonic) of the phase modulation and a higher order harmonic, or two higher order harmonics.

It is also possible to use the amplitudes of more than two harmonics in the loop phase error estimate, if desired, although using only two harmonics is preferred as this simplifies the estimation process, while still providing sufficient accuracy.

In a particularly preferred embodiment the amplitude of the forward signal components at the fundamental and second harmonic frequency of the phase modulation (i.e. at the particular frequency and at twice that frequency), preferably on their own, are measured and used to estimate the loop phase error. The loop phase error estimate is relatively straightforward when using these frequencies. Also, the amplitudes of lower order harmonics are easier to measure and can be more reliably measured, whereas higher order harmonics will have relatively smaller amplitudes, with a commensurate increase in difficulty in measuring them accurately.

The amplitude of the forward path signal of the amplifier can be measured in any suitable manner known in the art, and using any suitable measuring means or detector. For example, where an envelope detector is provided to analyse the output signal of the amplifier (such as might be the case in an RF amplifier), the envelope detector can also be used to measure the amplitude of the components of the forward signal (in this case the frequency upconverted output signal) of the amplifier at the two frequencies.

The measurements of the forward signal of the amplifier at the two frequencies may be made consecutively, but preferably they are made simultaneously in order to reduce the amount of time taken to re-calibrate the amplifier.

The amplitude of the overall output signal of the amplifier (e.g. the up-converted and power amplified output signal to be supplied to the antenna of an RF-power amplifier) can be considered. Alternatively, the amplitude of the forward signal at another point in the forward signal path, for example after the feedback signal input to the forward signal path but before up-conversion to carrier frequency in an RF-amplifier, can be considered. The forward signal should be measured after the point where the feedback signal and input signal (i.e. the original signal to be amplified) are combined in the forward path of the amplifier.

Thus in one embodiment, the forward signal amplitude measurements are taken from the overall output signal of the amplifier (e.g. from the upconverted and power amplified output signal to be supplied to an antenna in an RF amplifier).

In such an arrangement where the amplifier is a Cartesian loop amplifier, one channel of the amplifier (i.e. the I or Q channel) inside the feedback loop should be disabled (i.e. switched off) so as not to contribute to the forward signal so that it does not disturb the measurement. One channel can conveniently be disabled by providing a switching means for switching it out of the feedback loop.

In a particularly preferred embodiment, the forward signal is measured at a point before any power or gain control (e.g. to adjust or align the amplifier for better performance) is applied to the forward signal. (As described in, for example, EP-A-0638994, it can be useful to apply gain control in the forward path of a power amplifier circuit.)

Thus in the case of a Cartesian loop RF amplifier the input signal to the amplitude measuring means (e.g. envelope detector) is preferably taken from a point after the forward signal is upconverted to radio frequency, e.g. after the forward-path summing junction (i.e. where the I and Q channels are recombined in the forward path), but before any forward path power or gain control means.

The Applicants have recognised that where the amplitude measurement is taken after a forward path power control means of the amplifier, the relevant detector or measuring means is exposed to the full range of the resulting signal level variation and therefore must operate correctly over at least this range. While this can be achieved, it places greater requirements on the detector and increases its complexity.

However, the Applicants have also recognised that in a feedback system, if the loop gain is sufficient, the signal at a point before any power control is carried out is sufficiently similar to the overall output signal of the amplifier that the operation of any adjustment or alignment processes can be based on either signal without any significant change in the amplifier's performance. Thus, operational adjustments to correct the performance at the output of the power amplifier can be satisfactorily based on parameters derived from detecting the forward signal before any power control is applied.

However, by extracting the required signals from a point in the amplifier system before forward path power or gain control is employed, the dynamic range over which the detection system is required to operate is reduced. Thus by detecting the amplifier's performance at a point before the power control is applied, the dynamic range requirement imposed on the detection system is much reduced, but without prejudice to the performance of the overall amplifier arrangement.

Furthermore, detecting the forward signal at this point reduces the risk of the amplifier's overall output signal being affected or degraded by spurious harmonics reflected or caused by the signal detection system (such as might be the case in an RF amplifier where an envelope detector is arranged to detect the output signal of the amplifier that is transmitted to an antenna).

It is believed that detecting the amplifier's performance at the point in an amplifier system before power control is applied would generally be advantageous, and not just in the context of the present loop phase error estimation process. Thus according to a third aspect of the present invention, there is provided a power amplifier having a power control means in its forward signal path and at least one negative feedback loop, in which a detection system is arranged to detect signals from the amplifier for control purposes, and wherein the detection system is arranged to detect the forward signal of the amplifier at a point before the power control means in the forward signal path of the amplifier.

According to a fourth aspect of the present invention, there is provided a method of operating a power amplifier having power control in its forward signal path and a negative feedback loop, and in which signals from the forward path of the amplifier are detected for control purposes, comprising detecting the signals from the amplifier for control purposes at a point before power control is applied to the forward signal of the amplifier.

In another particularly preferred embodiment where the amplifier is a Cartesian loop amplifier, the forward signal of the amplifier is measured from either the I or Q forward channel of the amplifier before the I and Q channel signals are recombined and before any upconversion of the signals, i.e. the baseband signal in the I or Q channel of the forward path of the amplifier is measured. In this arrangement the measurements are preferably also taken before any power amplification of the forward path signal.

The Applicants have recognised that the forward signal measurement can be taken at this point, because if the feedback loop is closed then the baseband signal in the I or Q channel is closely related to the envelope of the corresponding signal after recombination and up conversion to carrier frequency (subject to the signals possibly being of different power levels). This means that the amplitude components for estimating the phase error suitable for use in the present invention can be determined by measuring the relevant components in the baseband signal in the I or Q channel as well as by considering the envelope of the upconverted output signal.

However, it is advantageous to take the signal measurements at baseband at this point in the circuit, because then there is no longer a need to disable one or other of the Cartesian channels whilst performing the measurements. This is because at this point in the circuit the two channels do not interfere with each other (since their signals are in quadrature).

Avoiding the need to disable the I or Q channel simplifies the Cartesian loop circuits since it is no longer necessary to provide means for disabling one of the channels. More significantly, it avoids the problem of the carrier nulling signal from one channel being switched off when a channel is disabled. (As is known in the art, any d.c. offset in the forward path of the amplifier (e.g. caused by imperfections in the amplifier system) will appear as a carrier level in the output signal and therefore be fed back as a d.c. level in the feedback loop. Typically, a carrier nulling voltage is input to the Cartesian loop amplifier to account for such carrier leakage.) However, by disabling one of the Cartesian channels, the carrier nulling applied by that channel is lost. This could therefore lead to errors in the amplifier operation, which would be undesirable when measurements are being taken to determine parameters for the amplifier operation.

A further problem with the loss of carrier nulling is that high carrier levels can then arise. This can give transient switching problems at the start of a linearisation burst when the ramping up of the power is shaped by the switch-on characteristic of the Cartesian loop and is not filtered.

A further advantage of measuring the signal at baseband in one of the Cartesian channels is that such a measurement, in contrast to e.g. using an envelope detector to measure the amplitude modulation on the power amplified output, is not subject to an input level variation dependent on the power setting of the amplifier (which can make measurement difficult at the lowest power setting).

The outputs of the amplifier measured at the two harmonic (e.g. fundamental and second harmonic) frequencies of the phase modulation can be used as desired to evaluate the loop phase error. The exact relationship to use will depend on the accuracy of the loop phase error estimate desired. Preferably the relationship comprises the ratio of the two amplitudes taken to respective rational powers. As mentioned below, in one embodiment these powers are 1 and 0.5, i.e one amplitude is divided by the square root of the other.

In a particularly preferred embodiment the amplitude measurements at the harmonic frequencies are normalised to take account of any uniform scaling factors that may exist for all terms of the output signal (e.g. due to the power output of the amplifier and the sensitivity of the measurement system) and the normalised amplitudes then used to estimate the loop phase error. Preferably the scale factor is estimated by evaluating the d.c. component of the measured forward signal. Thus, most preferably the normalisation is carried out by dividing the amplitude measurement(s) by the d.c. component's amplitude. This can be done either on the overall forward signal before the amplitudes of the components at the harmonic frequencies are determined, or on the individual components themselves.

It is not essential to normalise the amplitude measurements, but doing so provides a more accurate estimate of the loop phase error (since it takes account of the scaling factor mentioned above).

In a particularly preferred embodiment, the loop phase error Φₒ (in radians) is estimated as follows:

$${Φ}_{o} = \frac{{A}_{1 f}}{2 \sqrt{{A}_{2 f}}}$$

where A_{1f} and A_{2f} are the normalised amplitudes of the output of the amplifier at the fundamental frequency and second harmonic frequency, respectively, of the feedback signal phase modulation.

In a particularly preferred embodiment, the estimated loop phase error is used to adjust the phase of the loop feedback signal to try to correct for and reduce or minimise the loop phase error. Thus the apparatus of the present invention preferably further comprises means for adjusting the overall or mean phase of the feedback signal, which means is controlled in accordance with the estimated loop phase error.

The correction signal which is applied to the amplifier to alter the mean or nominal phase of the feedback signal can be applied as desired. It can be applied anywhere in the amplifier loop, since this will still have the effect of altering the feedback signal's mean phase. Thus, a phase correction signal could be applied to the signal in the forward path of the closed amplifier loop. However, preferably the correction signal is applied to the feedback path of the amplifier loop for convenience.

One correction process to try to reduce or eliminate the loop phase error would be to iteratively hunt for the minimum of the estimated loop phase error, for example by applying successive, e.g. predetermined, stepwise phase alterations until the loop phase error estimates indicate that the minimum loop phase error has been crossed. The process could then be repeated but changing the loop phase in smaller steps in the opposite direction until the minimum is crossed again and so on, as desired, to try to get closer to the actual minimum. This process may be continued until the smallest possible modification to the control input signal (e.g. one bit for a digital system) altering the loop phase causes the loop phase error to change signs. Alternatively, the iteration may be stopper earlier.

The size of phase alteration steps could be varied in accordance with the magnitude of the estimated loop phase error, if desired. For example the step size could be selected from two or more predetermined magnitudes in accordance with the estimated loop phase error magnitude. However, preferably only the sign of the loop phase error, and not its magnitude, is considered. In this arrangement the error in the phase of the feedback signal would be reduced step wise until the sign of the loop phase error estimate changes (indicating that the minimum has been crossed). This is a particularly straightforward minimum hunting process and is suitable because the sign of the loop phase error differs either side of its minimum.

Instead of iteratively hunting the loop phase error minimum, the phase shift estimated as being necessary to compensate or correct substantially for the estimated loop phase error could be attempted to be made in one step by applying the required control input to get the phase shift element or means to effect the necessary phase shift (which would normally be a phase shift substantially equal and opposite to the estimated loop phase error).

In this arrangement the control input to effect a given phase shift is preferably varied in accordance with the operating or environmental conditions of the amplifier. This provides more accurate control, since, as is known in the art, the transfer function (i.e. the relationship between the control input and the phase-shift output) of the phase shift element or means may vary in an imprecisely know manner depending on environmental or in use conditions such as operating frequency or temperature.

Thus, for example, the control inputs for particular phase shift outputs could be derived empirically for one or more sets of environmental or in use conditions, and stored as predetermined look-up tables, or used to derive a mathematical model of the transfer function, for future use.

However, most preferably the relationship between the control signal input to the phase shift means and the phase shift effected thereby (i.e. the transfer function of the phase shift means) is estimated in use or in operation of the amplifier, preferably as part of the loop phase error correction process. From this relationship the control signal to be applied to the phase shift means to effect the correction phase shift indicated by the loop phase error estimate can be derived. This arrangement is advantageous because it yields an approximation to the transfer function for the presently prevailing operating conditions, i.e. it is a real time empirical estimate, but without the need to derive and store look-up tables or equations that may have to account for many different operating conditions.

The relationship between the control signal applied and phase shift is preferably derived by determining and comparing the loop phase errors for two different control signal inputs to the phase shift means (i.e. when two different phase shifts are applied by the phase shift element to the phase of the feedback loop). Preferably the difference between the control signal inputs i.e. the net input signal, is related to the difference between their respective loop phase errors, i.e. the net phase shift due to the control signal inputs. Because the transfer function can be approximated to a line for small absolute values of the phase shift, even though in reality it may not be linear, most preferably the ratio between the net phase shift and the net control signal input is determined. This yields a linear relation between input signal and phase shift which can be used to derive the control signal to apply to add a particular value of phase shift. This linear relation is the gradient of the tangent to the transfer function, and thus the sensitivity of the phase-shift means, at the current loop phase error.

It is believed that the above method of estimating the transfer function (i.e. the relationship between the control signal applied and phase shift) of a phase shift element is novel and inventive in its own right, and not necessarily only in the context of the foregoing loop phase error estimation aspects of the present invention

Thus when viewed from a further aspect, the present invention provides a method of approximating the transfer function of a phase shift means arranged to alter the phase of the feedback signal in a negative feedback amplifier, comprising: applying a first control signal to said phase shift means to bias the phase of the feedback signal of said amplifier; determining a parameter representative of the loop phase of said amplifier when said first control signal is applied; applying a second different control signal to said phase shift means to bias the phase of the feedback signal; determining a parameter representative of the loop phase when said second control signal is applied; and estimating the transfer function of the phase shift means on the basis of the two control inputs and the determined loop phases.

When viewed from a yet further aspect, the invention provides an apparatus for approximating the transfer function of a phase shift means arranged to alter the phase of the feedback signal in a negative feedback amplifier, comprising: means for applying a first control signal to said phase shift means to bias the phase of the feedback signal of said amplifier; means for determining a parameter representative of the loop phase of said amplifier when said first control signal is applied; means for applying a second different control signal to said phase shift means to bias the phase of the feedback signal; means for determining a parameter representative of the loop phase when said second control signal is applied; and means for estimating the transfer function of the phase shift means on the basis of the two control inputs and the determined loop phases.

In these aspects of the invention, the transfer function is preferably estimated, as above, by calculating the difference between the first and second loop phase measurements to a give net phase shift, calculating the difference between the first and second control inputs to give a net input signal, and relating the net phase shift to the net input signal (preferably by determining their ratio).

In the above two aspects of the present invention, the parameters representative of the loop phases could be actual loop phase estimates, but preferably are the respective loop phase errors. These errors are preferably determined by modulating the phase of the feedback signal of the amplifier, and considering the amplitude of the one or more harmonics of the forward signal of the amplifier, and most preferably of two or more harmonics as in the first two aspects of the present invention.

In use of the present invention, the loop phase error estimate and/or correction can be carried out as desired, and preferably at regular and/or predetermined intervals during operation of the amplifier.

Each estimation process would normally be performed in a particular predetermined, e.g. linearisation, timeslot, when the test signal and the modulating signal can be applied without interfering with other operations of the amplifier. A number of successive estimations could be made in the same, or successive, such time slots, where, for example, they are necessary to estimate the transfer function of a phase shift means. Each estimation yields a numerical value for the loop phase error, from which it can be determined whether a, and if so, what, correction to the loop phase is required.

The loop phase error values which the present invention yields are preferably stored. They may be used e.g. as a historical record or for monitoring purposes, if desired—e.g. the rate at which the phase error drifts could be monitored to give an indication of the state of service of a transmitter utilising the amplifier.

Although the loop phase error estimate is normally carried out in particular predetermined timeslots, the loop phase correction to linearise the amplifier does not have to be performed at any particular time. Thus, it can be and is preferably carried out substantially immediately just before transmission of the signal to be broadcast in an RF amplifier. By correcting the loop phase error at the time a message is to be transmitted, the present invention reduces the possibility of the correction being made erroneous by intermediate ambient condition changes (as noted above, the linearity of an amplifier is affected by ambient conditions).

As discussed above and will be demonstrated below, the present invention, particularly in its preferred embodiments, makes it possible to determine quickly a relatively accurate and reliable estimate of the absolute loop phase error. Since a more accurate value of the error is obtained, the corresponding loop phase error correction can be made more reliably and accurately. This will reduce the number of steps necessary to reduce the error to a desired limit. Indeed, the present invention potentially permits a satisfactory correction to be made in a single step.

By reducing the required number of correction steps, the loop phase error correction may be carried out more quickly and therefore with less disruption to the normal operation of the amplifier. This makes it more acceptable to carry out the calibration more often, thereby enabling the loop phase error and hence the linearity of the amplifier to be kept within tighter tolerances. An RF amplifier which is well linearised is advantageous, inter alia, because it creates less interference to other radio users.

Furthermore, by reducing the required number of correction steps the present invention reduces the number of linearisation bursts (which would still normally be required in the present invention to estimate the error, even if the actual correction is performed later) needed in an RF amplifier for linearising in advance of transmitting the actual message which is to be delivered. This reduces the time taken for linearising before transmission. Thus, the amplifier can be ready for operation more quickly, and therefore has an advantage in competing for channel access over amplifiers which take longer to linearise.

Reducing the transmission of linearisation bursts has several other benefits. For example battery power is saved because less energy is emitted by the radio. Also less heat is generated internally, reducing the heat dissipation requirements, and the temperature rise caused by linearisation (thus reducing the possibility of this temperature rise making the applied correction erroneous). The efficiency of use of the radio spectrum can also be increased.

In a particularly preferred embodiment, the present invention further comprises measuring one or more parameters indicative of the amplifier's operating conditions and adjusting the phase of the feedback signal of the amplifier or the correction to be applied thereto on the basis of the measured parameters. The adjustment is preferably done in a predetermined manner. As noted above, ambient conditions can affect amplifier performance. Thus by compensating for the measured actual operating or ambient conditions, more accurate linearisation that can take account of condition changes between making loop phase error estimate and phase correction calculation, and actually applying the correction can be achieved. Preferably the measurement and adjustment is made immediately prior to every transmission burst.

The types of parameters measured should be those which influence amplifier operation and linearity and thus could be, for example, the temperature at one or more points in the amplifier circuit, the amplifier load VSWR (voltage standing wave ratio) and/or the supply voltage under transmitter load.

The adjustments to make can be predetermined by e.g. deriving them from predetermined look-up tables, graphs, or mathematical relationships derived empirically from testing amplifiers under known or standard conditions.

Preferably, however, a correction factor for the measured parameter or parameters is determined in use, during operation of the amplifier. This could be achieved by relating the calculated phase correction, the actual phase correction applied and the measured contemporaneous parameter value to calculate a correction factor for the parameter for use in subsequent loop phase error evaluations. For example an initial loop phase error correction may take no account of the temperature of the amplifier. However the temperature at the time the initial calculated phase correction is applied may be measured and stored together with the values of the calculated and actual phase corrections applied and used to derive a temperature correction factor. When subsequent phase corrections are made, the temperature of the amplifier may be measured and taken into account using the temperature correction factor previously derived.

The invention may be used for any negative feedback amplifier, although it is particularly suited for use with linear power amplifiers such as a Cartesian loop amplifier in which separate feedback signals are applied to each of two quadrature components.

The method and apparatus of the invention can be used for, for example, radio-frequency power amplifiers, such as would be used in radio transmitters and mobile radio equipment.

The method and apparatus of the invention may be implemented using pure hardware means such as discrete components or hard-wired logic gates. Alternatively, the invention may be implemented at least partially using software, e.g. computer programs. It will thus be seen that when viewed from a further aspect, the present invention provides computer software specifically adapted to carry out the methods hereinabove described when installed on data processing means.

Furthermore it will be appreciated that the means specified in the apparatus of the invention may similarly comprise computer software specifically adapted to carry out the methods hereinabove described when installed on data processing means.

The invention also extends to a carrier comprising such software which when used to operate an apparatus for estimating the loop phase error in a negative feedback amplifier comprising a digital computer, causes, in conjunction with said computer, said apparatus to carry out the steps of the method of the present invention. Such a carrier could be a physical storage medium such as a ROM chip, CD ROM or disk, or could be a signal such as an electronic signal over wires, an optical signal or a radio signal such as to a satellite or the like.

It will further be appreciated that not all steps of the invention need be carried out by computer software and thus from a further broad aspect the present invention provides computer software such software installed on a carrier for carrying out at least one of the steps of the methods set out hereinabove. Similarly, not all of the means specified in the apparatus of the invention need comprise computer software and thus in the general preferred case, it is at least one of such means which comprises computer software.

A number of preferred embodiments of the present invention will now be described, by way of example only, and with reference to the accompanying drawings, in which:

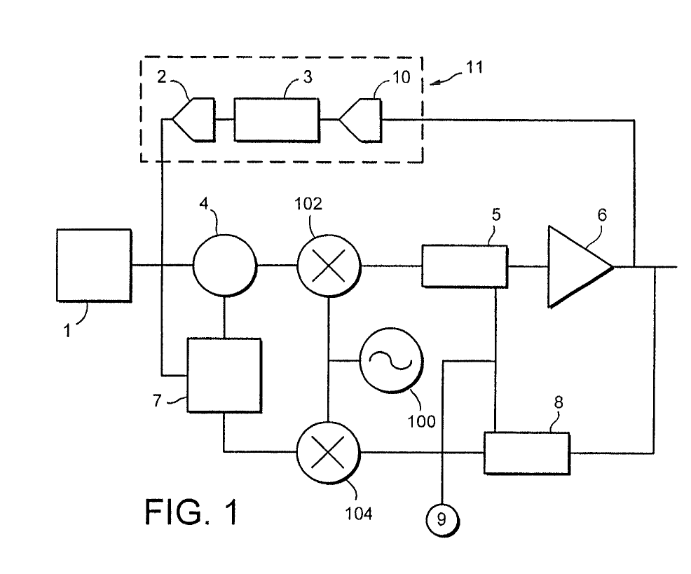

FIG. 1 shows a generalised arrangement of an amplifier with feedback to which the present invention can be applied;

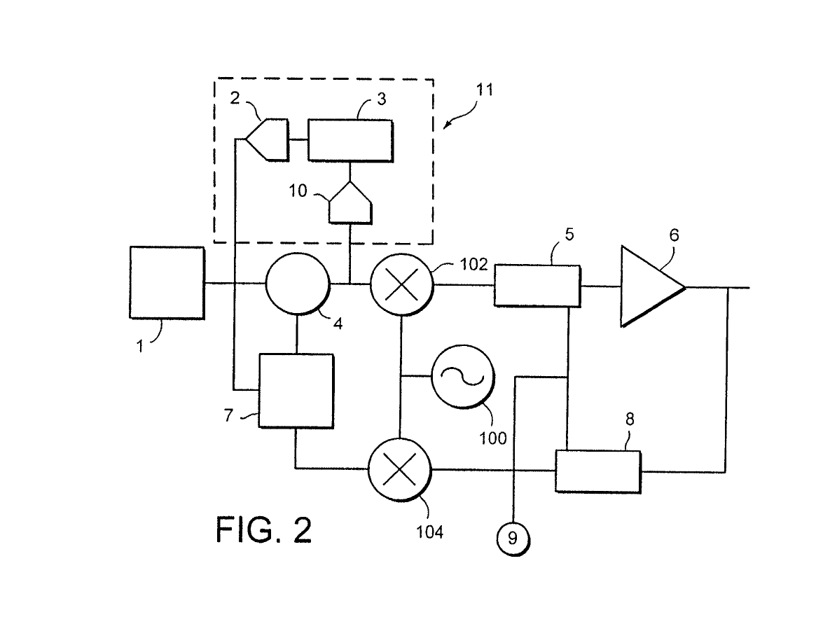

FIG. 2 shows an alternative arrangement for the amplifier of FIG. 1;

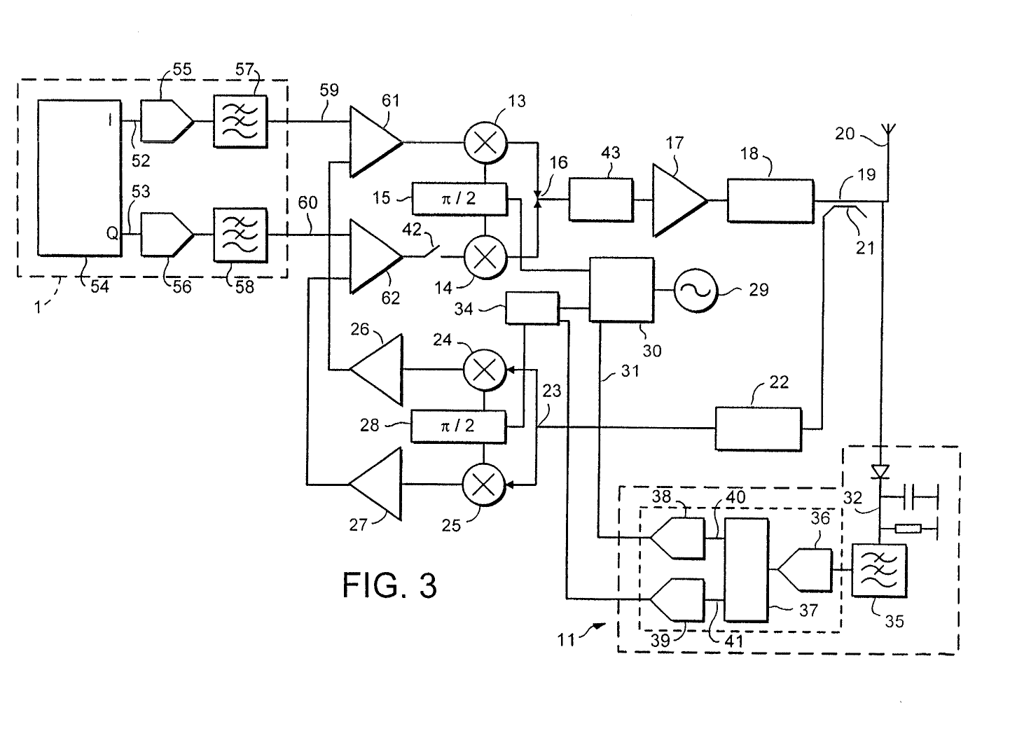

FIG. 3 shows a Cartesian loop amplifier which can be operated in accordance with the present invention;

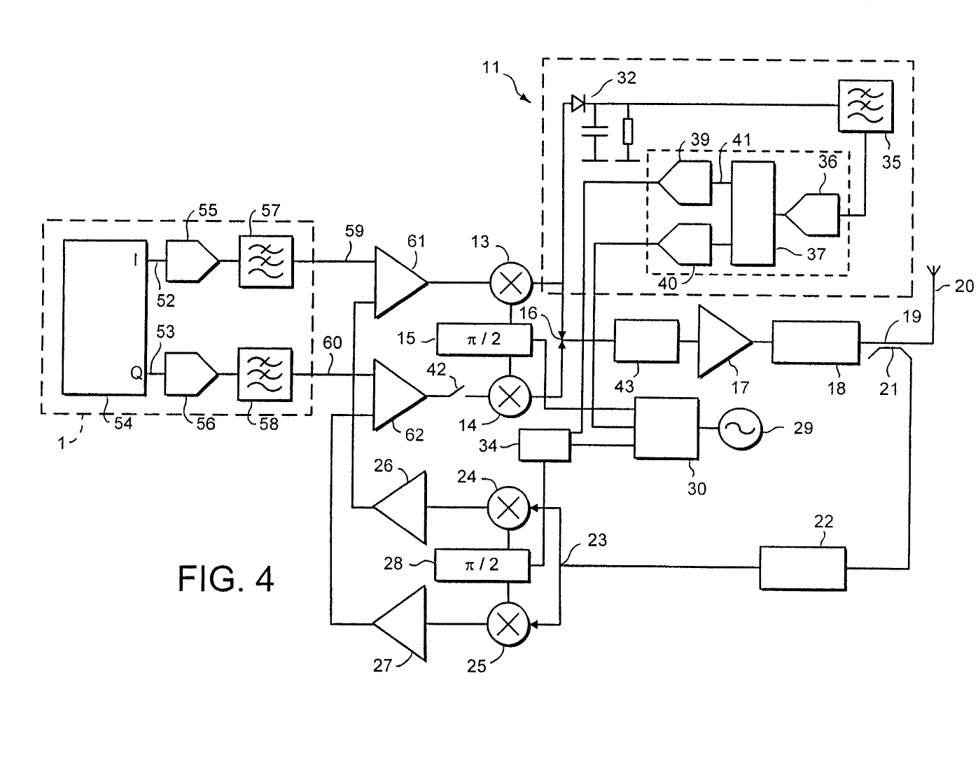

FIG. 4 shows a modified version of the Cartesian loop amplifier of FIG. 3;

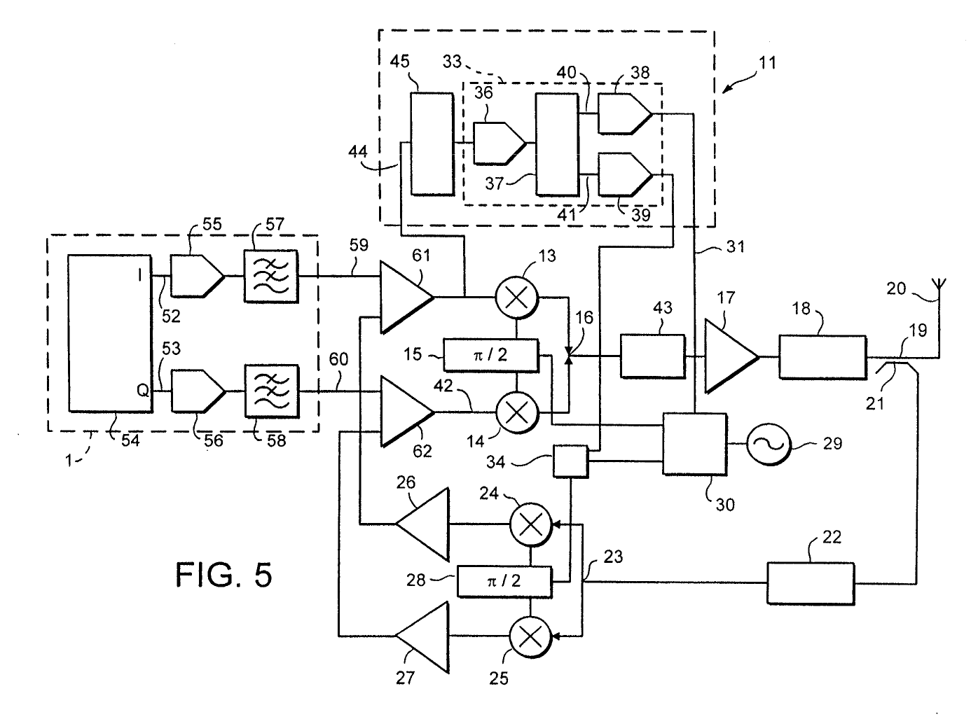

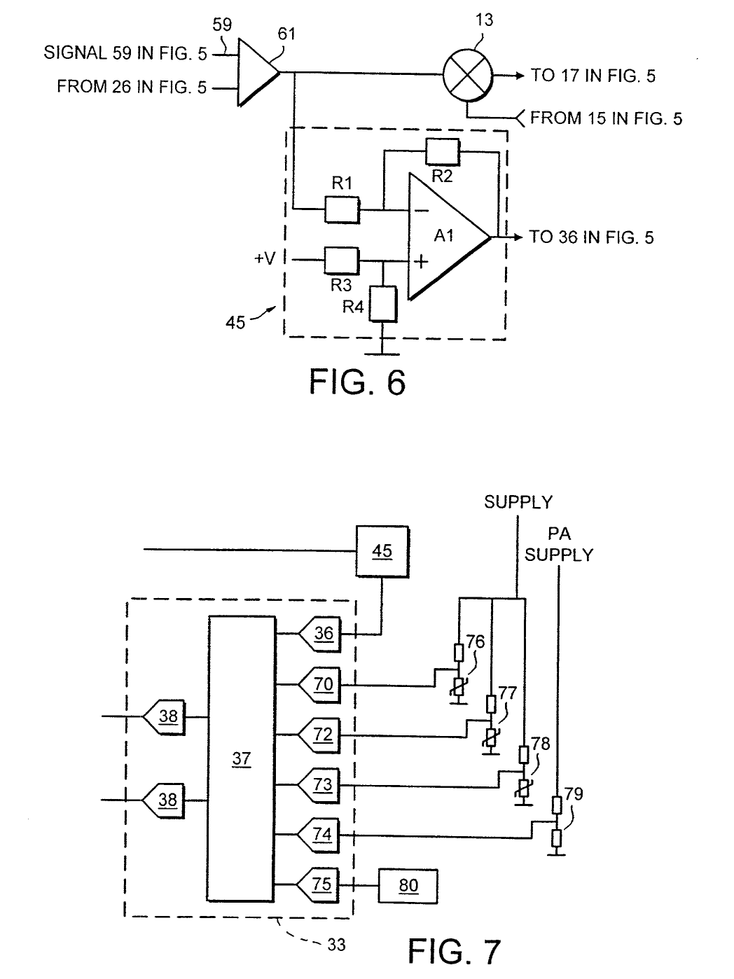

FIG. 5 shows a further alternative modification to the Cartesian loop amplifier of FIG. 3;

FIG. 6 shows in more detail the measuring arrangement of FIG. 5;

FIG. 7 shows a further modification to the amplifiers of FIGS. 3, 4 and 5; and

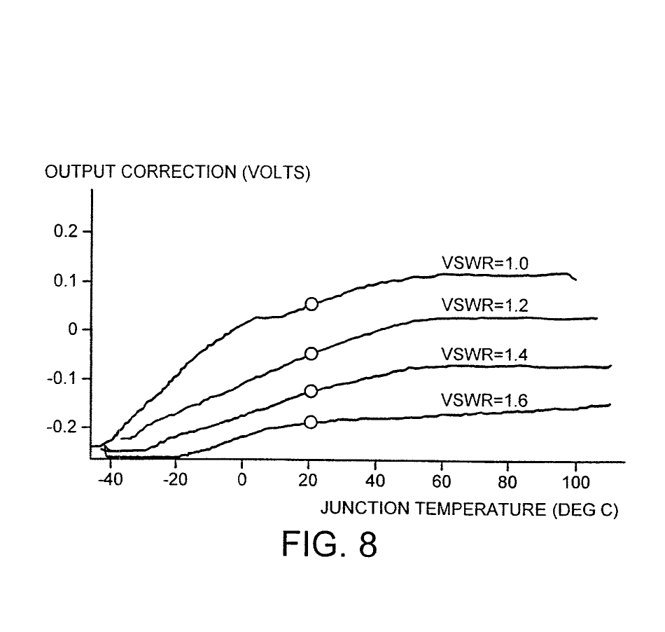

FIG. 8 is an exemplary graph of output correction against junction temperature and voltage standing wave ratio.

Like reference numerals are used for like components throughout the figures.

FIG. 1 shows a generalised arrangement of an amplifier with feedback. A signal source 1 for providing the input signal to be amplified is connected to a first input of a differencing amplifier stage 4. A second input of the differencing stage 4 receives a feedback signal to be added as a correction to the input signal in the differencing stage 4. The output of the differencing stage 4 is used to modulate a carrier signal produced by an oscillator 100 by means of a frequency up-conversion mixer 102. The output of the mixer 102 is supplied to a first gain control element 5 for modifying the forward path gain of the amplifier. The output of the gain control element 5 is supplied to an amplifier gain stage 6. The output of this amplifier gain stage 6 is the overall output of the amplifier circuit. Part of this overall output is also fed back as the feedback signal to the differencing stage 4 via a second gain control element 8, a down-conversion mixer 104 (which is also coupled to the oscillator 100 and down-converts the feedback signal to baseband) and a phase shift element 7.

The two gain control elements 5 and 8 can be controlled as discussed in, for example, EP-A-0638994, though an input 9 to control both the loop gain of the amplifier and to vary the overall power output of the amplifier. Element 8 controls the overall output power and element 5 is adjusted in sympathy to keep the feedback loop parameters constant and maintain loop stability.

The phase-shift element or means 7 controls the feedback loop phase. The shift of loop phase applied by the phase shift element 7 is determined by a control and measuring arrangement or means 11, shown in FIG. 1 as consisting of an analogue-to-digital convertor 10, processing means 3, and a digital-to-analogue convertor 2, which, inter alia, measures the overall output signal in the forward path from the output of amplifier gain stage 6. The phase is controlled to try to ensure that the amplifier is linear. Other measuring and signal detection arrangements are possible.

In use, the amplifier is operated in a negative feedback mode, as is known in the art.

The net input to the amplifier 4, taking into account the feedback path 7, 8 is:

net input=(Pᵢ−fPₒ)

where, Pᵢ is the input power;

Pₒ is the output power; and

f=fraction of output power which is fed back

i.e. the gain of the feedback loop.

The output power of the amplifier, Pₒ, is therefore given by the following formula:

Pₒ=G(Pᵢ−fPₒ) (1)

where G is the overall gain of the forward part of the loop, and thus includes amplifiers 4, 5 and 6 and any losses in this part of the circuit.

It will be seen from manipulation of equation (1) that:

$${P}_{o} ( 1 + f G ) = GPi ⇒ \begin{matrix}\frac{{P}_{o}}{{P}_{i}} = \frac{G}{1 + f G} = \begin{matrix}the overall gain of \\ the amplifier\end{matrix} \\ = \frac{1}{1 / G + f}\end{matrix}$$

Assuming G is very large the first term in the denominator may be ignored and thus:

$$\frac{{P}_{o}}{{P}_{i}} \approx \frac{1}{f} \qquad ( 2 )$$

In practice, when a loop phase error, Φ, exists between the input and feedback signals (i.e. their phase deviates from the ideal phase relationship by an amount Φ), the feedback fraction will be a function of the phase error Φ (in radians).

In particular, f=fₒcos Φ where fₒ is the nominal gain of the feedback loop. Thus substituting in equation (2),

$$\frac{{P}_{o}}{{P}_{i}} \approx \frac{1}{{f}_{o} cos Φ} \qquad ( 3 )$$

Hence it will be seen that for a given input the measured output power as shown by the measuring means 11 is inversely proportional to the cosine of the loop phase error, Φ.

At certain intervals, e.g. periodically, it becomes necessary to correct the loop phase error of the amplifier to maintain the overall response of the amplifier within acceptable tolerances.

In order to correct the loop phase error in accordance with the invention, the amplifier is put into a set-up mode and the loop phase error estimated. A d.c. test signal is applied by the signal source 1 to the input of the differencing amplifier stage 4. Although a d.c. test signal is used in order to give a simple output signal, any suitable signal may be used.

It can be shown that in general the cosine function may be expanded as an infinite power series

$$cos x \approx 1 - \frac{{x}^{2}}{2 !} + \frac{{x}^{4}}{4 !} - …$$

In the present case, substituting this approximation in equation (3) gives:

$$\frac{{P}_{o}}{{P}_{i}} \approx \frac{1}{{f}_{o} ( 1 - \frac{{Φ}^{2}}{2 !} + \frac{{Φ}^{4}}{4 !} - … )}$$

The loop phase error, Φ is assumed to be small and therefore the term in Φ⁴ is negligible, resulting in:

$$\frac{{P}_{o}}{{P}_{i}} \approx \frac{1}{{f}_{o} ( 1 - \frac{{Φ}^{2}}{2} )} \qquad ( 4 )$$

It can also be shown that in general for |x|<1,

$$\frac{1}{1 - x} \approx 1 + x + {x}^{2} + {x}^{3} + …$$

substituting x=Φ²/2 and ignoring terms of order greater than Φ², equation(4) gives

$$\frac{{P}_{o}}{{P}_{i}} \approx \frac{1}{{f}_{o}} ( 1 + \frac{1}{2} {Φ}^{2} )$$

which may be rewritten as:

A=k (1+½Φ²) (5)

where k is a constant scaling factor (defined by the nominal power output of the amplifier and the sensitivity of the measuring arrangement 11 in this embodiment) and A is the output level of the measuring arrangement 11, i.e of the forward signal (in this case the overall output signal of the amplifier).

In accordance with the invention, to estimate the loop phase error, while the amplifier is in the set-up mode, the phase of the feedback signal is modulated by a measuring oscillation, which can be applied by the phase shift element 7 (e.g. under suitable control from the processing means 3), such that the actual phase of the feedback signal

Φ=Φₒ+d. sin ωt

where Φₒ is the nominal or mean phase shift existing in the feedback loop, and d is the amplitude and ω the frequency of the phase modulating signal. Any suitable frequency for the phase modulating signal may be chosen. For example, for convenience a frequency used elsewhere in the equipment may be utilised so that in practice a common oscillator can be used. Thus in a TETRA (TErrestrial Trunked RAdio) system, a frequency of 2.25 kHz could be used. In RF power amplifiers in general, a frequency of around 2 kHz would be suitable, although other frequencies are possible.

Substituting in equation (5),

A=k(1+½(Φₒ+d. sin ωt)²)

Since the loop phase error has a negligible effect on the d.c. component of the output signal when, as has been assumed above, it is small, the value of the scaling factor, k, can be determined by measuring the d.c. component of the envelope curve (i.e. k(1+½Φₒ²)≅k). This determined value of k can then be used to derive the following equation:

A′=1+½(Φₒ²+2Φₒd. sinωt+d² sin² ωt)

where A′ is the normalised output to take account of the value of k determined (i.e. the overall output divided by the determined value of k (the amplitude of the d.c. component of the output signal)).

Multiplying out,

A′=1+½Φₒ²+Φₒd. sin ωt+½d² sin² ωt

Using the trigonometric relation,

2 Sin ²x=1−cos2x

gives:

A′=1+½Φₒ²+Φₒd. sin ωt +¼d²(1−cos 2ωt)

Thus measurement of the normalised amplitude of the component of the output at the fundamental frequency of the phase modulation yields the coefficient of the sin ωt term, i.e.

A_{1f}=Φₒd

It should be noted that this term is proportional to d, the amplitude of the phase modulating signal. This amplitude of the modulating signal can in practice be difficult to determine and/or set accurately (a nominal value will for example vary with operating and environmental condition changes). Thus although the amplitude of the first harmonic can give a measure of the loop phase error, it may not be entirely reliable or accurate, as it depends on another parameter which can vary in use.

The normalised amplitude of the component of the overall output at the second harmonic (i.e. twice the frequency of the phase modulation) yields the coefficient of the cos2ωt term,

$${A}_{2 f} = \frac{{d}^{2}}{4}$$

Eliminating d gives:

A_{1f}=2φₒ\sqrt{A}_{2f}

and thus

$${Φ}_{o} = \frac{{A}_{1 f}}{2 \sqrt{{A}_{2 f}}} \qquad ( 6 )$$

Thus the loop phase error, Φₒ, may be determined by measuring the d.c. component of the output signal and the components of the output signal curve at the fundamental and second harmonics of the modulating oscillation. (It should be noted that the expression for the loop phase error is an approximate one, although the approximation is a good one for small values of the error such as are typically encountered in the preferred embodiments of the invention.)

The present invention thus gives an estimate of the absolute value of the loop phase, and which is not dependent on any other variable parameters that cannot readily be determined or set precisely in the estimation process. It therefore provides a more accurate and reliable estimate of the loop phase error, but which can still be quickly and readily determined using a small number of signal measurements.

It should be noted that although in the above equation (6) the harmonics' amplitude values are normalised by dividing them by the d.c. component of the forward signal, it is not essential to do that. If the d.c. component is not considered, equation (6) becomes:

$${Φ}_{o} = \frac{{A}_{1 f}}{2 \sqrt{{kA}_{2 f}}}$$

Thus a factor of 1/√k appears in the estimate. This may not be a problem where a less accurate estimate is sufficient or desired, or the term √k has in practice a small or negligible effect on the calculation.

Once Φₒ has been evaluated, this value can be used to adjust the phase shift element 7, to try to correct or reduce the loop phase error. The estimated value of Φₒ is preferably stored and used to make a correction to the loop phase just before transmission of a message. The correction can be done, for example, by hunting the minimum of the loop phase error or by trying to apply a phase correction to compensate for it, as noted above.

The loop phase error estimation and correction process can be repeated, as desired, to reduce the loop phase error further. Once the error is within a desired limit, the amplifier can transmit its data.

The invention permits a sufficient loop phase correction to be made in a single step when the error is small or a small number of steps if the initial error is too large for the approximations made in the above derivation to hold, such that the amplifier can quickly be adjusted to operate in a sufficiently linear mode.

FIG. 2 shows an improved version of the FIG. 1 amplifier circuit. In this arrangement, the measuring means 11 measures the forward signal from before the forward path gain control element 5, that is before any power control is applied in the amplifier's forward path.

The advantage of this arrangement is that unlike the arrangement shown in FIG. 1, the signal input level to the measuring means 11 does not vary in accordance with the power output of the closed-loop system (which, as noted above, is designed to be adjustable). This is because where, as in the arrangement of FIG. 2, the power control of the amplifier is achieved by simultaneous adjustment of gain control elements 5 and 8, the signal level at the output of differencing stage 4 (i.e. before the input to gain control element 5), is, in the ideal case, constant. Thus the signal level at the input to analogue-to-digital convertor 10 does not vary as the amplifier power output is adjusted. This considerably reduces the dynamic range to which the measuring arrangement 11 is subjected, thereby simplifying the circuits that can used for that arrangement.

An illustrative arrangement of a Cartesian loop RF amplifier (i.e. an amplifier in which an input signal to be amplified is represented by orthogonal vectors I (in-phase) and Q (quadrature phase)) corresponding to the general amplifier arrangement shown in FIG. 1 and to which the invention can be applied is shown in FIG. 3.

In the amplifier of FIG. 3 a signal source (referred to generally by the numeral 1) provides the input signal to the amplifier (i.e. the signal to be amplified). The signal source 1 includes a digital modulator 54 that produces an output signal which is made available in the form of two quadrature components I and Q. These quadrature components are provided on two outputs 52,53 of the modulator 54, and are applied to the inputs of two digital-to-analogue converters 55 and 56 respectively.

The outputs of these converters are filtered by low pass filters 57 and 58 respectively in order to remove unwanted artefacts produced by the digital-to-analogue conversion process, and the outputs of the filters 57 and 58 are applied as amplifier input signals to the non-inverting inputs of two differencing amplifiers 61 and 62 respectively (which correspond to the amplifier stage 4 of the embodiments of FIGS. 1 and 2). The differencing amplifiers 61 and 62 each also have an inverting input to which the appropriate quadrature component of a correction (feedback) signal is applied. The differencing amplifiers combine the input signal and the correction signal and output the resulting combined signals.

In order to convert the output signals of the differencing amplifiers 61 and 62 to the desired RF carrier frequency, the outputs of the differencing amplifiers 61 and 62 are applied to the inputs of two up-conversion mixers 13 and 14 respectively of a first mixer stage. The mixers 13, 14, combine the components of the output signals of the differencing amplifiers 61, 62 with RF wavetrains of a first oscillation of a local oscillator 29. In fact two wavetrains are used, the wavetrains being phase shifted through 90° relative to each other by a phase shifter 15 to provide appropriate I and Q components.

The outputs of mixers 13 and 14 are combined additively by a summing means 16 to form an up-converted output signal. This output signal is applied to the input of a power amplifier comprising a gain control element 43, a driver stage 17 and an output stage 18. The power amplifier power amplifies the up-converted signal to a power level suitable for use and supplies it to the amplifier load such as an antenna 20 (which then radiates the amplified signal).

A coupler 19 is also arranged in the output path to feedback a (lower level) coupled output 21 comprising part of the output signal of the power amplifier 18 to a feedback path for the derivation of the correction feedback signal which is applied to the inverting inputs of the differencing amplifiers 61, 62.

The feedback path firstly comprises a level-setting element 22, an attenuator in this example, for altering the signal level which is to be input to the feedback circuit. The output of the attenuator 22 is then applied to a series of components which derive a baseband representation of the feedback in the form of quadrature feedback components for applying as correction signals to the differencing amplifiers 61 and 62.

The feedback signal is firstly split into two identical signals by a signal splitter 23. These two signals are then mixed with RF wavetrains of a second oscillation of the local oscillator 29 to down-convert them to baseband frequency by frequency down-conversion mixers 24 and 25 of a second mixer stage. The wavetrains are phase-shifted by 90° with respect to each other by a second phase shifter 28 so that appropriate quadrature (i.e. I and Q) baseband feedback signals are derived. The feedback signals are down-converted by the same frequency value as the input signal was up-converted.

The down-converted feedback signals are connected to the inputs of two further level-setting elements 26 and 27 respectively, which in this example are amplifiers. The purpose of level-setting elements 26 and 27 is to adapt the amplitude between the input signal and the feedback (correction) signal and these amplifiers may be omitted, as appropriate.

The (amplitude-adjusted) baseband I and Q feedback signals are then applied to the inverting inputs of the differencing amplifiers 61 and 62 respectively as feedback signals that are subtracted from the signal inputs 59 and 60 respectively.

As discussed above, the wavetrains for up-converting the forward signal to carrier frequency, and for down-converting the feedback signal to baseband are derived from a local oscillator 29. The local oscillator 29 produces a signal at the RF carrier frequency of the overall output of the amplifier. The above two oscillations of the local oscillator are then derived from this wave form by means of a phase adjustor or phase shift means or element 30. The phase position of at least one of these oscillations of the local oscillator can be adjusted by an adjusting signal which is applied to the phase adjustor 30 through an adjusting input 31.

The phase adjustor 30 produces two outputs. The first output is the up-conversion wavetrain, which is applied to the input of a Π/2 phase-shift element 15, from which I and Q up-conversion wavetrains are produced for use in up-conversion mixers 13 and 14. The second output of the adjustor 30 is the down-conversion wavetrain which is applied to the input of a second Π/2 phase-shift element 28 from which the I and Q down conversion wavetrains for use in the down-conversion mixers 24 and 25 are produced, via a phase modulator 34. The phase modulator 34 controls the phase of these signals so as to modulate the phase of its output with respect to its input to provide a phase modulation of the loop phase.

A measuring arrangement 11 is also provided to measure and analyse the output signal of the amplifier. In this embodiment the measuring arrangement 11 comprises an envelope detector 32 arranged to detect the signal at the output of the amplifier, the output of which is applied to the input of a processing means 33 which can be used to control the phase adjustor 30 and the phase modulator 34 (and other aspects of the amplifier system, if desired), as is known in the art. The processing means 33 typically comprises an analogue-to-digital converter 36, a digital signal processor 37, and digital-to-analogue converters 38 and 39. Optionally a low-pass filter 35 is also provided. The digital signal processor functions to evaluate the envelope curve signal and can comprise digital switch means for this purpose.

As for the amplifier of FIGS. 1 and 2, this Cartesian loop amplifier is operated in use in a negative feedback mode. Thus equation (2) above applies.

As before, when a loop phase error, Φ, exists between the input and feedback signals, the feedback fraction will be a function of the phase error Φ (in radians), and thus, from equation (3), for a given input the output power as shown by the envelope curve detector 32 is inversely proportional to the cosine of the loop phase error, Φ.

At certain intervals, e.g. periodically, it becomes necessary to correct the loop phase error of the amplifier to maintain the overall response of the amplifier within acceptable tolerances.

In order to correct the loop phase error in accordance with the invention, the amplifier is put into a set-up mode as above, and the loop phase error estimated. In this mode the Q quadrature channel is interrupted by a switch 42 so that operation of the I channel Loop is not disturbed by operation of the Q channel loop. A d.c. test signal is applied by the signal source 1 to the I channel input of the differencing amplifier 61. Although a d.c. test signal is used in order to give a simple carrier output signal, any suitable signal may be used.

As before it can be shown that

A=K (1+½Φ²) (5)

where k is a constant scaling factor (defined by the nominal power output of the transmitter and the sensitivity of the envelope detector 32 in this embodiment) and A is the output level of the envelope curve detector 32.

In accordance with the invention, to estimate the loop phase error, while the amplifier is the set-up mode, the phase of the feedback signal is modulated by a measuring oscillation such that the actual phase of the feedback signal

Φ=Φₒ+d. sin ωt

where Φₒ is the nominal or mean phase shift existing in the feedback loop, and d is the amplitude and ω the frequency of the phase modulating signal. A suitable frequency for the phase modulating signal in a TETRA RF power amplifier would be 2.25 kHz, although other frequencies are possible.

The measuring oscillation is applied by the phase modulator 34 under the control of the digital signal processor 37. To do this, the digital signal processor 37 generates a digital measuring signal on its second output 41, from which signal an analog measuring oscillation is formed in the subsequent digital to analog converter 39. The output of the digital to analog converter 39 forms a modulation output which is applied to the phase modulator 34. The phase modulator 34 modulates the phase position of the second oscillation of the local oscillator, on its way from the phase adjustor 30 to the second phase shifter 28, in accordance with the applied modulation output. The applied phase modulation, as is apparent from the above, appears as a resulting amplitude modulation of the output envelope curve signal, which can be evaluated by the digital signal processor 37 (via the analog/digital convertor 36).

As before substituting in equation (5) gives,

A =k(1+½(Φₒ+d. sin ωt)²)

As before, since the loop phase error has a negligible effect on the d.c. component of the output signal when, as has been assumed above, it is small, the value of the scaling factor, k, can be determined by measuring the d.c. component of the envelope curve. This determined value of k can then be used to derive the following equation:

A′=1+½(Φₒ²+2Φₒd. sin ωt+d² sin²ωt)

where A′ is the normalised output to take account of the value of k determined (i.e. the overall output divided by the determined value of k (the amplitude of the d.c. component of the envelope curve)). Thus again

$${Φ}_{o} = \frac{{A}_{1 f}}{2 \sqrt{{A}_{2 f}}} \qquad ( 6 )$$

where A_{1f} is the normalised amplitude of the component of the envelope curve at the fundamental frequency of the phase modulation and A_{2f} is the normalised amplitude of the component of the envelope curve at the second harmonic frequency of the phase modulation.

Thus as before, the phase loop error, Φₒ, may be determined easily by measuring the d.c. component of the output signal envelope curve and the components of the output envelope curve signal at the fundamental and second harmonics of the applied phase modulating oscillation.

In accordance with the loop phase error determined, the digital signal processor 37 generates a digital adjusting signal on its first output 40 to correct for the determined loop phase error. This adjusting signal is converted in the subsequent digital to analog converter 38 into an analog adjusting signal which is applied to the adjusting input 31 of the phase adjustor or phase shift means 30. The phase adjustor 30 adjusts the phase of at least either oscillation of the local oscillator in accordance with the adjusting signal. For example, only the first or the second oscillation of the local oscillator can be adjusted, but the two may also be adjusted in opposite directions, etc.

In a particularly preferred arrangement, the control signal for the phase adjuster 30 to achieve the desired phase correction (i.e. the transfer function of the phase adjustor 30) is derived concurrently with the loop phase error evaluation process. This can be done by applying a first control signal to the phase adjustor 30, to bias the phase of the feedback signal from its nominal value, e.g. to effectively add a small positive d.c. bias to the sinusoidal phase modulation signal applied by the phase modulator 34, and evaluating the loop phase error. A second, different control signal should then be applied to the phase adjustor 30, e.g. to bias the phase of the feedback signal from its nominal value in the opposite direction to effectively add a small negative d.c. bias to the sinusoidal phase modulation signal, and the loop phase error again evaluated. The difference between the loop phase errors is the loop phase shift resulting from a control input whose magnitude is the difference between the first and second control signals (i.e. the positive and negative bias levels). This gives a measure of the phase adjustor's sensitivity at the current operating point. From this the requisite control signal to achieve a given phase shift can be determined.

The above correction process can be repeated as desired, to try to reduce the loop phase error further. For example the transfer function estimation process can be used as a step in a Newton-Raphson type iteration.

FIG. 4 shows a modified version of the Cartesian loop amplifier of FIG. 3. In the arrangement shown in FIG. 4 the input to the measuring means 11 (via the level detector 32) is taken from the forward path summing junction 16, i.e. before the forward path gain control element 43 and before the variable signal level applied by the gain control element 43. Thus the embodiment of FIG. 4 corresponds to the embodiment of FIG. 2.

It is possible to take the measurements from the summing junction 16 in this manner because in the feedback system illustrated, if the loop gain is sufficient, then the signal properties of the signal at the summing junction 16 and the signal at the output of the power amplifier are sufficiently similar that the operation of any adjustment or alignment process can be based on either signal.

The advantage of taking the measurement at this point is that if power control of the amplifier is achieved by simultaneous adjustment of gain control elements 26, 27 and 43, as discussed, for example, in EP-A-0638994, then the signal level at summing junction 16 is, in the ideal case, constant. Thus the signal level at the input to the measuring means 11 in the embodiment shown in FIG. 4 does not vary as the amplifier output power is adjusted. This considerably reduces the dynamic range to which the measuring means 11 and in particular the envelope curve detector 32 is subjected.

FIG. 5 shows a further Cartesian loop amplifier arrangement that can be operated in accordance with the present invention. In this arrangement the measuring and control means 11 is arranged to take as its input signal the baseband signal in the I channel, i.e. the signal output from the differencing amplifier 61 and before upconversion by the upconversion mixer 13. In this arrangement, because the signal being measured is at baseband, there is no need to use an envelope curve detector, but instead a more simple measuring element 45 can be used to detect the level of the baseband signal.

Of course, the signal could be taken from the Q channel instead of the I channel, if desired.

FIG. 6 shows in more detail a suitable arrangement for the measuring element 45. It comprises a typical amplifier arrangement comprising an operational amplifier A1 the gain of which is set by resistors R1 and R2. Resistors R3 and R4 are used to bias the amplifier so its output falls within the operating range of the analogue to digital convertor 36 in FIG. 5.

The Applicants have recognised that if the feedback loop is closed then the baseband signal at the output of differencing amplifier 61 in FIG. 5 (i.e. in the I channel before upconversion) has the same characteristic as the envelope of the corresponding upconversion mixer output. Thus the components that indicate the phase error in the loop (which in the embodiments of FIGS. 3 and 4 are measured from the envelope of the upconverted output) can be determined instead by measuring the components of the baseband signal in magnitude and phase at the two harmonics of the test modulation frequency.

The advantage of this arrangement is that there is no need to disable the Q channel while a measurement is being made. Thus the switch 42 can be eliminated. More importantly, any carrier nulling applied by the Q channel is no longer lost whilst the measurements are being made. This, inter alia, means that the carrier power level will be sufficiently low that the energy in the adjacent channel due to transient switching at the start of linearisation burst will be greatly reduced.

As noted above, one significant advantage of the present invention is that it reduces the requirement for transmitting linearisation bursts in advance of transmitting the actual message which is to be delivered in an RF amplifier. One of the reasons for the need for the linearisation time burst in an RF power amplifier is to adjust the amplifier to operate in a sufficiently linear mode as soon as the next message is to be transmitted. However, the Applicants have recognised that the linearity of a Cartesian loop amplifier, for example, is affected by ambient conditions. Adjustment of the loop feedback parameters is a means of compensating for these conditions. However, conditions may change between linearisation and transmitting a message and/or between the phase correction calculation and actually making the phase correction.

Thus in particularly preferred embodiments of the present invention there is further provided a mechanism which can take into account ambient conditions affecting the performance of the transmitter, and compensate for them at the time that real transmissions are required. This may make it unnecessary to transmit linearisation bursts, although more probably, linearisation bursts will be generated from time to time to check the optimal operation of the amplifier, but their use may not always be essential to linearising the transmitter sufficiently to be within specification limits.

Thus in the present invention it is preferred to monitor one or more parameters indicative of the ambient or environmental conditions of the amplifier, such as the junction temperature of the power amplifier transistor(s), the junction temperatures of the driver stages, the load VSWR (voltage standing wave ratio) and/or the supply voltage under transmitter load, and make them available as additional inputs into the processing means 33 which controls the phase adjustor and the phase modulator. The processing means 33 can then use these parameters to further modify the phase of the feedback loop to correct for ambient conditions.

The measurements of these parameters can be taken as desired. Suitable sensors should be arranged appropriately in the amplifier circuits and their outputs provided as inputs to the digital signal processor 37 of the processing means 33.

FIG. 7 shows a measurement and control arrangement circuit suitable for use in the Cartesian loop amplifiers of FIGS. 3, 4 and 5. A number of measuring means 76, 77, 78, 79 and 80 are provided to measure the ambient conditions of the amplifier. Measuring means 78 measures the temperature of the driver transistor, measuring means 79 measures the power amplifier supply voltage, and measuring means 80 measures the VSWR at the output of the power amplifier. Measuring means 76 and 77 measure the heat-sink temperature at two points differing in separation from the power amplifier transistors and thus will reveal a temperature gradient which will further enhance the ability of processing means 33 to estimate the junction temperature. Generally speaking, the heat-sink temperature should be measured close to the power amplifier and driver transistor. Thus, in a more simple implementation, measurement of heat-sink temperature close to the main heat-generating device would suffice. As an alternative to this arrangement, it is possible to obtain a power-amplifier device which contains an additional p-n junction specifically for the purpose of measuring the junction temperature of the device.

All the measuring means are connected appropriately to the amplifier processing means 37 of the processing means 33 by means of analogue-to-digital convertors 70 to 75 which convert the analogue voltages measured by the measuring means 76, 77, 78, 79 and 80 to digital values.

In operation, processing means 37 will measure the temperatures, VSWR and battery voltage inputs and use them to modify its output from digital to analogue convertors 38 and 39 to adjust the phase adjustor and phase modulator to correct for the measured conditions, just prior to every transmission burst. During linearisation bursts, the measuring arrangement 11 may be used to verify the outputs from convertors 38 and 39.

The corrections to be applied in accordance with the ambient conditions can be stored as phase adjustment information in a set of look-up tables, with the processing means 37 selecting the appropriate table depending on the temperature, voltage and/or VSWR settings (or interpolating between tables). Alternatively, a mathematical relationship could be predetermined and programmed into the processing means 37, for example using a set of calibration constants. Alternatively, a combination of these methods could be employed. FIG. 8 illustrates a possible look-up graph for deriving the correct output corrections from a combination of VSWR and junction temperature measurements. A similar graph could be drawn for battery voltage and temperature of VSWR observations.

The table values (for example the graph of FIG. 8) and calibration constants would be determined during set up of the amplifier, either by full measurement of the amplifier (which would be time consuming), or preferably by measurement of a few calibration values which would permit the amplifier to use known temperature, VSWR and voltage characteristics previously determined by extensive measurements of example amplifiers. For example the shapes of the curves in FIG. 8 could be recorded from specimen amplifiers, but their precise positioning in the vertical direction could be determined by individual calibration of actual amplifiers at room temperature by making linearisation measurements at a limited number of voltage and VSWR settings (for example as illustrated by the small circles in FIG. 8). The actual corrections to apply can be derived by measuring calibrated output values for digital to analogue convertors 38 and 39 during manufacture and storing them in processing means 37.

Although the present invention has been described above in terms of measurement of the forward signal at the fundamental and second harmonic of the phase modulation frequency, other harmonics may be used in order to evaluate the loop phase error. This would necessitate retaining more of the terms of the approximation used in the above derivation. An example of this is discussed below.

From equation (4) above:

$$\frac{{P}_{o}}{{P}_{i}} = \frac{1}{{f}_{o} ( 1 - \frac{{Φ}^{2}}{2} )} \qquad ( 4 )$$

As before, using the expansion where |x|<1,

$$\frac{1}{1 - x} \approx 1 + x + {x}^{2} + {x}^{3} + …$$

and putting x=Φ²/2, but this time only ignoring terms greater than Φ⁴

$$\frac{{P}_{o}}{{P}_{i}} \approx \frac{1}{{f}_{o}} ( 1 + \frac{{Φ}^{2}}{2} + \frac{{Φ}^{4}}{4} )$$

or

A=k(1+½Φ²+¼Φ⁴)

Putting Φ=Φₒ+d. sin ωt:

A=k(1+½(Φₒ+d. sin ωt) ²+¼(Φₒ+d. sin ωt)⁴)

k{1+½(Φₒ²+2Φₒd. sin ωt+d². sin²ωt) +¼(Φₒ⁴4Φₒ³d. sin ωt +6Φₒ²d². sin²ωt+4Φₒd³. sin³ωt +d⁴. sin⁴ωt)} (7)

≡Cₒ+C₁ sin ωt+C₂ sin²ωt+C₃ sin³ωt+C₄ sin⁴ωt (8)

Now,

2 sin² a=1−cos 2a [symbol] sin²a=½(1−cos 2a) (9)

Therefore, from equation (9)

$$\begin{matrix}{sin}^{4} a = \frac{1}{4} {( 1 - cos 2 a )}^{2} \\ = \frac{1}{4} ( 1 - 2 cos 2 a + {cos}^{2} 2 a ) \\ but {cos}^{2} 2 a = 1 - {sin}^{2} 2 a \\ = 1 - \frac{1}{2} ( 1 - cos 4 a ) \\ = \frac{1}{2} ( 1 + cos 4 a )\end{matrix}$$

Thus substituting gives:

$$\begin{matrix}{sin}^{4} a = \frac{1}{4} ( 1 - 2 cos 2 a + \frac{1}{2} + \frac{1}{2} cos 4 a ) \\ = \frac{3}{8} - \frac{1}{2} cos 2 a + \frac{1}{8} cos 4 a\end{matrix} \qquad ( 10 )$$

We now have expressions for sin² and sin⁴ in terms of multiple angles, therefore only sin³ remains:

$$\begin{matrix}{sin}^{3} a = sin a {sin}^{2} a \\ = \frac{1}{2} sin a ( 1 - cos 2 a ) \\ = \frac{1}{2} ( sin a - sin a cos 2 a )\end{matrix}$$

=½(sin a−sin a cos 2a)

Using the appropriate trigonometric relation,

2 sin p cos q=sin (p+q)+sin (p−q)

gives:

$$\begin{matrix}{sin}^{3} a = \frac{1}{2} \{ sin a - \frac{1}{2} ( sin ( a + 2 a ) + sin ( a - 2 a ) ) \} \\ = \frac{1}{2} \{ sin a - \frac{1}{2} ( sin 3 a - sin a ) \} \\ = \frac{1}{2} ( \frac{3}{2} sin a - \frac{1}{2} sin 3 a ) \\ = \frac{1}{4} ( 3 sin a - sin 3 a )\end{matrix} \qquad ( 11 )$$

Thus substituting the above derived ‘a’ relations in the ‘ω’ expression, equation (8) becomes

A=Cₒ+C₁(sin ωt)+C₂(1−cos 2ωt) +C₃(¼(3 sin ωt−sin 3ωt) +C₄(⅜−½cos 2ωt +⅛cos 4ωt)

Thus the amplitude at the ith harmonic, A_{if} is:

A_{1f}=C₁+¾C₃

A_{2f}=C₂+½C₄

A_{3f}=¼C₃

A_{4f}=⅛C₄

From equation (7):

C₁=k (Φₒd+Φₒ³d) =kΦₒd (1+Φₒ²)

C₂=k(½d²+3/2Φₒ²d) =k.½d²(1+3Φₒ²)

C₃=kΦₒd³

C₄=¼kd⁴

[symbol]

A_{1f}=kΦₒd (1+Φₒ²+¾d²)

A_{2f}=k.½d² (1+3Φₒ²+¼d²)

A_{3f}=¼kΦₒd³

$${A}_{4 f} = \frac{{kd}^{4}}{32}$$

Normalising to cancel k gives

A′_{1f}=Φₒd (1+Φₒ²+¾d²)

A′_{2f}=½d² (1+3Φₒ²+¼d²)

$${A}_{3 f}^{′} = \frac{{Φ}_{o} {d}^{3}}{4}$$

$${A}_{4 f}^{′} = \frac{{d}^{4}}{32}$$

It is clear that any two of these equations may be solved for d and Φ. The simplest such solution is:

d=(32A′_{4f})

Φₒ=4A′_{3f} (32A′_{4f})^{-¾}

In other words the two variables may be found by measuring any two convenient harmonics or may be found more accurately by measuring 3 or more harmonics and averaging the estimate of Φₒ and d which these yield.

1. A method of estimating the loop phase error in a negative feedback amplifier, comprising applying a test signal to the input of the amplifier, modulating the phase of the feedback signal to be summed to the test signal input to the amplifier, measuring the amplitude of the forward signal of the amplifier at two harmonics of the frequency of the phase modulation, and estimating the loop phase error on the basis of said two amplitude measurements.

2. A method as claimed in claim 1, wherein the test signal is a D.C. level.

3. A method as claimed in claim 1 or 2, wherein the phase modulation is applied to the signal in the feedback path of the amplifier.

4. A method as claimed in claim 1, 2 or 3, wherein the phase of the feedback signal is modulated at substantially a predetermined single frequency.

5. A method as claimed in claim 4 comprising measuring the amplitude of the forward signal at the said. frequency and its second harmonic to estimate the loop phase error.

6. A method as claimed in any one of the preceding claims, wherein the ratio of the two amplitude measurements taken to respective rational powers is used to estimate the loop phase error.

7. A method as claimed in any one of the preceding claims, wherein the amplitude measurements are normalised to take account of uniform scaling factors.

8. A method as claimed in any one of the preceding claims comprising estimating the loop phase error Φₒ (in radians) using the expression
$${Φ}_{o} = \frac{{A}_{If}}{2 \sqrt{{A}_{2 f}}}$$
where A_{1f} and A_{2f} are the normalised amplitudes of the output of the amplifier at the fundamental frequency and second harmonic frequency, respectively, of the feedback signal phase modulation, said normalisation taking into account uniform scaling factors.

9. A method as claimed in any one of the preceding claims, wherein said amplifier is a Cartesian loop amplifier.

10. A method as claimed in any one of the preceding claims, comprising measuring the amplitude of said forward signal using the baseband signal in one of the forward channels of the amplifier.

11. A method as claimed in any one of the preceding claims, comprising measuring said forward signal at a point in the amplifier before power or gain control is applied thereto.

12. A method as claimed in any one of the preceding claims, comprising using the loop phase error estimate to adjust the phase of the loop feedback signal of the amplifier.

13. A method as claimed in claim 12 comprising adjusting the phase shift applied to the loop feedback signal in one or more steps until the sign of the loop phase error changes sign.

14. A method as claimed in claim 12 comprising applying a control input to a phase shift means to try to correct said loop phase error, the control input being determined by the loop phase error that is estimated.

15. A method as claimed in claim 14, comprising estimating a transfer function for the phase shift means during use of the amplifier, and determining the control input for the phase shift means on the basis of the loop phase error that is estimated and the estimated transfer function.

16. A method as claimed in claim 14, comprising estimating the transfer function for the phase shift means by comparing the loop phase errors for two different control inputs to the phase shift means.

17. A method as claimed in any one of the preceding claims, wherein the amplifier comprises a radio frequency amplifier, and the loop phase error estimation is carried out substantially immediately before transmission of a signal to be broadcast.

18. A method as claimed in any one of the preceding claims, comprising measuring one or more parameters indicative of the amplifier's operating conditions and adjusting phase of the feedback signal of the amplifier or the correction to be applied thereto on the basis of the measured parameters.

19. A method as claimed in claim 18, comprising determining, during operation of the amplifier, a correction factor for said one or more parameters to account for said operating condition or conditions.

20. A method of approximating the transfer function of a phase shift means arranged to alter the phase of the feedback signal in a negative feedback amplifier, comprising: applying a first control signal to said phase shift means to bias the phase of the feedback signal of said amplifier; determining a parameter representative of the loop phase of said amplifier when said first control signal is applied; applying a second different control signal to said phase shift means to bias the phase of the feedback signal; determining a parameter representative of the loop phase when said second control signal is applied; and estimating the transfer function of the phase shift means on the basis of the two control inputs and the determined loop phases.

21. A method of operating a power amplifier having power control in its forward signal path and a negative feedback loop, and in which signals from the forward path of the amplifier are detected for control purposes, comprising detecting the signals from the amplifier for control purposes at a point before power control is applied to the forward signal of the amplifier.

22. An apparatus for estimating the loop phase error in a negative feedback amplifier, comprising means for applying a test signal to the input of the amplifier, means for modulating the phase of the feedback signal to be summed to the test signal input to the amplifier, means for measuring the amplitude of the forward signal of the amplifier at two harmonics of the frequency of the phase modulation, and means for estimating the loop phase error on the basis of the two amplitude measurements.

23. An apparatus as claimed in claim 22, wherein the means for modulating the phase of the feedback signal is arranged to modulate the signal in the feedback path of the amplifier.

24. An apparatus as claimed in claim 22 or 23, wherein the modulating means is arranged to modulate said feedback signal at substantially a predetermined single frequency.

25. An apparatus as claimed in claim 24, wherein said means for measuring the amplitude of the forward signal is arranged to measure at the said frequency and its second harmonic to estimate the loop phase error.

26. An apparatus as claimed in any one of claims 22 to 25, wherein said means for estimating the ratio of the loop phase error uses the ratio of two amplitude measurements.

27. An apparatus as claimed in any one of claims 22 to 26, wherein said amplifier is a Cartesian loop amplifier.

28. An apparatus as claimed in any one of claims 22 to 27, wherein said means for measuring the amplitude of the forward signal is arranged to use the baseband signal in one of the forward channels of the amplifier.

29. An apparatus as claimed in any one of claims 22 to 28, wherein said means for measuring the amplitude of the forward signal is arranged to measure said forward signal at a point in the amplifier before power or gain control is applied thereto.

30. An apparatus as claimed in any one of claims 22 to 29, comprising means to adjust the phase of the loop feedback signal of the amplifier using the loop phase error estimate.

31. An apparatus as claimed in any one of claims 22 to 30, comprising means for measuring one, or more parameters indicative of the amplifier's operating conditions and means for adjusting phase of the feedback signal of the amplifier or the correction to be applied thereto on the basis of the measured parameters.

32. A power amplifier having a power control means in its forward signal path and at least one negative feedback loop, in which a detection system is arranged to detect signals from the amplifier for control purposes, and wherein the detection system is arranged to detect the forward signal of the amplifier at a point before the power control means in the forward signal path of the amplifier.

33. An apparatus for approximating the transfer function of a phase shift means arranged to alter the phase of the feedback signal in a negative feedback amplifier, comprising: means for applying a first control signal to said phase shift means to bias the phase of the feedback signal of said amplifier; means for determining a parameter representative of the loop phase of said amplifier when said first control signal is applied; means for applying a second different control signal to said phase shift means to bias the phase of the feedback signal; means for determining a parameter representative of the loop phase when said second control signal is applied; and means for estimating the transfer function of the phase shift means on the basis of the two control inputs and the determined loop phases.

34. Computer software specifically adapted to carry out the method of any of claims 1 to 21 when installed on data processing means.

35. A computer software carrier comprising software as claimed in claim 34, which, when used to control one or more digital computers within an apparatus for estimating the loop phase error in a negative feedback amplifier, causes said apparatus to carry out said method.

36. A method of estimating the loop phase error in a negative feedback loop amplifier substantially as hereinbefore described with reference to the accompanying drawings.

37. An apparatus for estimating the loop phase error in a negative feedback loop amplifier substantially as hereinbefore described with reference to the accompanying drawings.
